(19) United States
(12) Patent Application Publication
(10) Pub. No.: US 2007/0066071 A1
(43) Pub. Date: Mar. 22, 2007

(54) Novel organic remover for advanced reticle contamination cleaning

(75) Inventors: Chia-Hsien Chen, Puli Township (TW); Hsiang Chien Hsu, Toufen Town (TW); S.C. Hsu, Sijhih City (TW); Chian-Hun Lai, Hsinchu City (TW); Chun-Hung Kung, Hsinchu City (TW); Jong-Yuh Chang, Daya Township (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/261,116

(22) Filed: Oct. 28, 2005

Related U.S. Application Data
(60) Provisional application No. 60/718,118, filed on Sep. 16, 2005.

(51) Int. Cl. H01L 21/302; H01L 21/461

(52) U.S. Cl. 438/704; 438/747

(57) ABSTRACT

A method includes introducing an acid solution having ethanol and an acid to a substrate and cleaning the substrate using the acid solution; applying an ultrasonic wave to the acid solution substantially during the cleaning of the substrate; and performing a fine cleaning of the substrate after the cleaning of substrate with the acid solution.

### CROSS-REFERENCE

This application claims benefit and priority from U.S. Provisional Patent Application (Attorney Docket No. 24061.688), filed on Sep. 16, 2005 and entitled “NOVEL ORGANIC REMOVER FOR ADVANCED RETICLE CONTAMINATION CLEANING.”

### BACKGROUND

Reticle contamination introduced while removing a pellicle from a reticle may include pellicle glue contamination that is hard to remove. The current cleaning methods do not efficiently remove this glue-like contamination and may further cause damage to the reticle, especially to a patterned MoSi layer formed on a phase-shift mask (PSM).

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a flow chart of one embodiment of a method for cleaning a mask.

FIG. 2 is an exemplary photomask that can be cleaned using the method of FIG. 1.

FIG. 3 illustrates an exemplary setup for cleaning a mask using the method of FIG. 1.

FIG. 4 illustrates a block diagram of one embodiment of a cleaning system that can implement the method of FIG. 1.

### DETAILED DESCRIPTION

It is to understood that the following disclosure provides many different embodiments, or examples, for implementing different features of various embodiments. Specific examples of components and arrangements are described simplistically for purposes of clarity. These are, of course, merely examples and are not intended to be limiting.

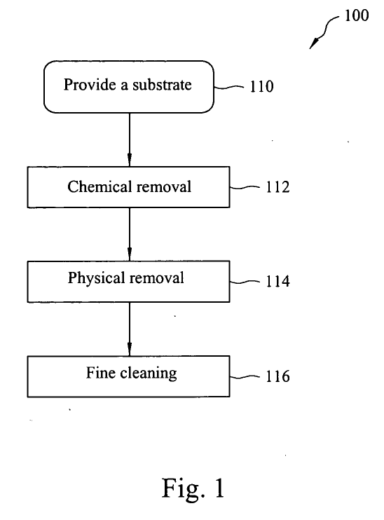

Referring to FIG. 1, a method 100 is used to clean a photomask that can be used to fabricate semiconductor wafers and the like. The photomask is also referred to as a mask or reticle. Even though the mask is employed as an example to illustrate the disclosed method and system, it is not limited to a mask cleaning process and may be extended to cleaning other substrates having similar contamination issues.

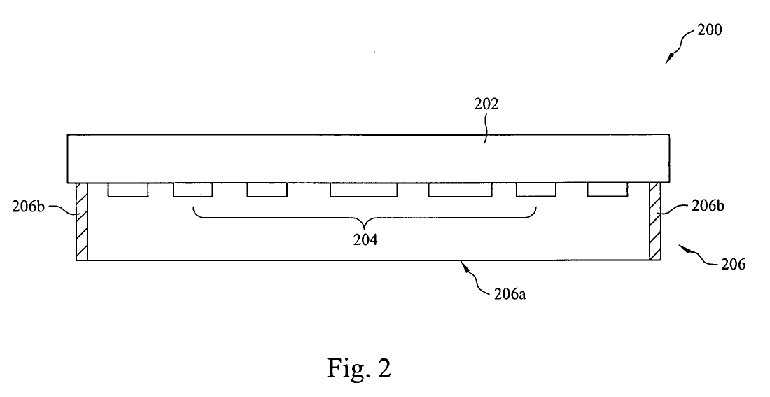

The method 100 begins at step 110 by providing a mask to be cleaned. FIG. 2 illustrates an exemplary mask 200. The mask 200 includes a transparent substrate 202 having fused quartz (SiO₂), calcium fluoride (CaF₂), or other suitable material. The mask further includes an absorption layer 204 formed on the transparent substrate, using chromium (Cr), iron oxide, or an inorganic film made with MoSi, ZrSiO, SiN, MoSiONₓ, and/or TiN. The absorption layer may have a multilayer structure. For example, the absorption layer may further include an anti-reflective coating (ARC) layer. The mask may further include patterned features (shifters) formed on/in the substrate to phase-shift a radiation beam shining therethrough. In one embodiment, the shifters may includes areas in which the substrate is partially etched such that the radiation beam through these areas have a predefined phase shift, such as about a 180 degree shift relative to areas not etched. In another embodiment, the shifters may be integrated with the absorption layer. For example, a MoSiONₓ layer may be coated on the substrate to have a partial absorption and a phase shift to the radiation beam. However, MoSiONₓ material is sensitive to base-containing solutions and can be damaged during a conventional cleaning process, resulting in further defects on the mask. The mask 200 may further include a pellicle 206 having a transparent membrane 206a and a frame 206b. The pellicle 206 is attached to and secured on the transparent substrate 202 to protect the substrate 202 from damage and contamination. The pellicle 206 may be attached to the substrate 206 by glue. When the mask 200 needs to be repaired during fabrication, the pellicle 206 may be detached, resulting in glue contamination to the mask. Thus the provided mask 200 may be with the pellicle 206 detached.

At step 112, the mask is cleaned in a chemical cleaning procedure using an acid solution. The acid solution may be a mixture of ethanol and acid. In one embodiment, the acid solution uses acetic acid (C₂H₄O₂) and may optionally include acetone in the acid solution. In one embodiment, the acid solution may be blended with about 0 to 8 acetone, 1 to 8 ethanol, and 0.1 to 5 acetic acid in relative volume, respectively. For example, the acid solution may be blended with about 6 acetone, 6 ethanol, and 1 acetic acid in relative volume, respectively. The acid solution may be maintained at a temperature ranging between about 10° C. and 50° C. during the cleaning. For example, the solution may be set at room temperature.

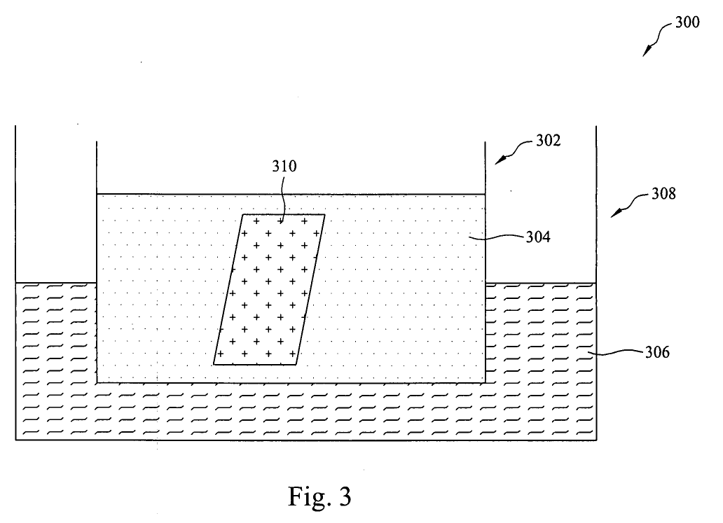

FIG. 3 is a diagrammatic view of an exemplary setup 300 to implement the chemical cleaning at step 112. The setup 300 includes a chemical tank 302 filled with the acid solution 304 described above. The acid solution 304 may be maintained at a predefined temperature by a water bath 306 and in an ultrasonic tank 308. A mask 310 such as the mask 200 of FIG. 2 is soaked in the acid solution 304. The ultrasonic wave may be utilized substantially during the chemical removal process to enhance the chemical removal. In one embodiment, the ultrasonic wave may have a frequency fixed at about 360 KHz and a power ranging between about 10 and 200 Watts. The chemical removal process may have a duration ranging between about 10 minutes and 80 minutes.

At step 114, the mask is physically cleaned using deionized water (DI water or DIW). The physical cleaning may be implemented in various modes including DI water shower, vapor, or dip. The DI water cleaning may be carried out using the ultrasonic wave similar to the one used in step 114 in terms of frequency, power, and setup. In one example, the physical cleaning at step 114 may resume after the completion of the chemical cleaning at step 112 in the same setup but changing from the acid solution to DI water. The physical cleaning may have a duration ranging between about 10 and 120 seconds.

At step 116, the mask may undergo further fine cleaning. The fine cleaning may be a modified version of a standard cleaning procedure. In one embodiment, the mask is cleaned using a SC-1 cleaning process. The SC-1 solution includes NH₄OH, H₂O₂, and H₂O. The SC-1 solution to be used may have a mixture of NH₄OH, H₂O₂, and H₂O with a relative volume of about 0 to 1, 2, and 100 to 600, respectively. The SC-1 solution may be maintained at a temperature ranging between about 50° C. and 150° C. during the fine cleaning. A megasonic wave may be applied to the SC-1 solution during the fine cleaning. In one example, the megasonic wave may have a fixed frequency at 1.02 MHz and a power ranging between about 100 watt and 550 watt. The fine cleaning at step 116 may have a duration ranging between about 5 and 60 minutes.

Step 116 may further include a drying process in which the mask, after all cleaning processes, is dried using isopropyl alcohol (IPA). IPA may be heated and maintained at a temperature ranging between about 50° C. and 150° C. The IPA drying process may have a duration between about 20 and 150 seconds. In one example, the mask is wetted by IPA vapor and then dried in air or an inert gas such as a nitrogen gas environment.

The mask thus cleaned may be further inspected for any remaining contamination and/or damage. The method 100 may be repeated to the mask if necessary.

The present disclosed method provides a base free environment for highly protective cleaning of masks, and for phase-shift masks in particular. The contamination from pellicle glue may include fluoropolymer with acrylate groups. For example, the glue contamination may include chemical groups such as an ester group. Esters may be hydrolyzed by the aqueous acid to yield carboxylic acids and alcohols. Polar groups in the contaminations may be changed by the acid solution into a more hydrophilic chemical and further dissolved in water. The disclosed method provides an efficient cleaning procedure, eliminates cleaning-associated damages to the mask such as damage to shifters of the phase-shift masks, and minimizes characteristic variance of phase-shift masks. The method can be extensively used to clean other types of masks and other suitable substrates.

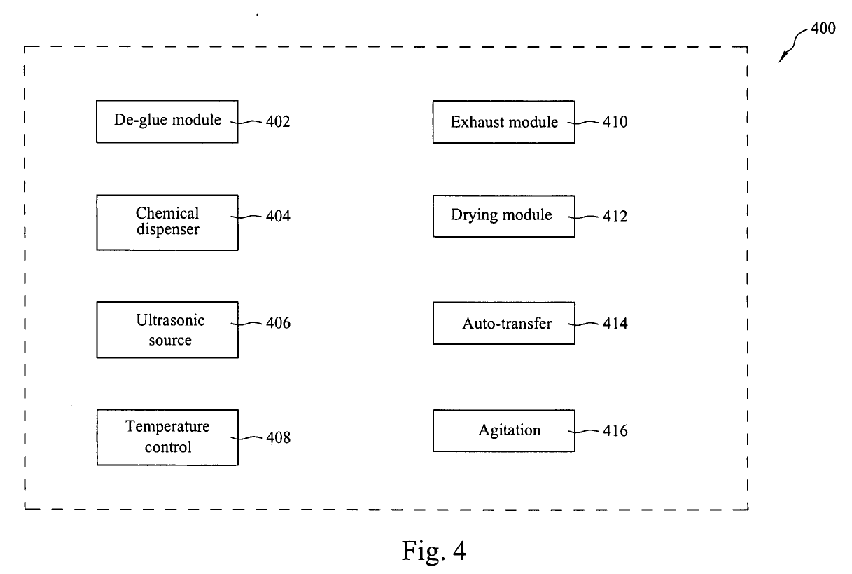

FIG. 4 is a block diagram illustrating an exemplary system 400 utilized to implement the method 100 for cleaning a mask. The system 400 includes a de-glue module 402 to detach an attached pellicle from a mask. The de-glue module 402 may dissolve the glue bonding the pellicle and substrate, and detach the pellicle from the substrate. The system 400 also includes a chemical dispenser 404 designed and configured such that various chemicals can be dispensed, blended at a predefined ratio, and sent to a cleaning location such as a cleaning tank, a cleaning chamber or other suitable configuration. In one example, the chemical dispenser 404 is designed to controllably dispense acetone, ethanol, acetic acid, IPA, and DI water.

The system 400 includes an ultrasonic source 406 to provide ultrasonic energy to various liquids. The ultrasonic source 406 may provide ultrasonic energy with various frequencies and an adjustable power level. For example, the ultrasonic source 406 may provide an ultrasonic power having a frequency of about 360 KHz and/or a megasonic power having a frequency of about 1 MHz. The ultrasonic power is generated thereby and transferred to a cleaning liquid such as acid solution, DI water, and SC-1 solution. The system 400 includes a temperature control module 408 to control the temperature of various cleaning liquids and the environment. The temperature control module 408 may further include heaters and thermal sensors configured for temperature control.

The system 400 may further include an exhaust module 410 to exhaust chemical gases. The exhaust module 410 may additionally be designed and configured to exhaust chemical liquids. The system 400 may further include a dry module 412 to dry a cleaned substrate. The dry module 412 may be integral to other modules of the system 400 to perform a drying process. The system 400 may further include an auto-transfer 414 such as a robotic hand to automatically transfer a work piece (such as a mask). The system 400 may further include an agitation mechanism such as a controller for a magnetic bar to agitate a chemical solution for mixing and cleaning. The agitation module 416 may be integral to other modules of the system 400, such as the ultrasonic source 406 and may utilize the ultrasonic power for realizing the agitation. The system 400 may include other components such as a power supply, electrical control, operator interface, and a cleaning chamber or a tank configured to implement the method 100 for effective cleaning of substrates such as PSM substrates.

Thus, the present disclosure provides a method for substrate cleaning. The method includes introducing an acid solution having ethanol and an acid to a substrate, and cleaning the substrate using the acid solution; applying an ultrasonic wave to the acid solution substantially during the cleaning of the substrate; and performing a fine cleaning of the substrate after the cleaning of the substrate with the acid solution.

In the disclosed method, the introducing of the acid solution may include introducing acetic acid. The method may further include introducing acetone into the acid solution. The method may further include introducing the acid solution blended with about 0 to 8 acetone, 1 to 8 ethanol, and 0.1 to 5 acetic acid in relative volume, respectively. The method may further include maintaining the acid solution at a temperature ranging between about 10° C. and 50° C. The cleaning of the substrate may have a duration ranging between about 10 minutes and 80 minutes. The applying of the ultrasonic wave may include applying the ultrasonic wave having a power ranging between about 10 and 200 Watts. The applying of the ultrasonic wave may include applying the ultrasonic wave having a frequency of about 360 KHz. The substrate may be a mask. The mask may include a material selected from the group consisting of SiO₂, Cr, and MoSiONₓ. The performing of the fine cleaning may include performing a cleaning to the substrate using a SC-1 solution blended with about 0-1 NH₄OH, 2 H₂O₂, and 200-600 H₂O in relative volume, respectively; and applying to the SC-1 solution a megasonic wave having a power ranging between about 100 and 550 Watts. The performing of the fine cleaning may further include performing a drying process using isopropyl alcohol (IPA) for a duration ranging between about 20 to 150 seconds. The performing of the drying process may include maintaining the IPA at a temperature ranging between about 50° C. and 150° C. The method may further include a physical cleaning using de-ionized water (DIW) and ultrasonic waves after the cleaning of the substrate using the acid solution. The physical cleaning may include introducing DIW in one mode selected from the group consisting of showering, vaporization, dipping and combinations thereof. The physical cleaning may include introducing to the substrate ultrasonic wave having a power ranging between about 10 and 200 Watts. The physical cleaning may have a duration ranging between about 10 seconds and 120 seconds.

The present disclosure also provides a system used for cleaning. The system includes a de-glue module designed for removing a pellicle from the substrate of a reticle through removing glue disposed at an interface between the pellicle and the substrate; a chemical dispenser designed for providing various chemicals to form an acid solution used to clean the reticle; an ultrasonic source designed for providing various ultrasonic waves used to enhance the cleaning of the substrate; and a temperature control module configured to control the chemicals' temperature. The system may further include an exhaust module designed for removing exhaustive gases and used chemicals; and a drying module designed for drying the substrate. The system may further include a mechanism to automatically transfer the substrate; and an agitation module configured to provide agitation to various solutions.

The present disclosure also provides another method for substrate cleaning. The method includes performing a chemical cleaning to a substrate using an acid solution containing acetone, ethanol, and acetic acid; performing a physical cleaning to the substrate using deionized water (DIW); and performing a fine cleaning using a solution containing NH₄OH, H₂O₂, and H₂O.

While the preceding description shows and describes one or more embodiments, it will be understood by those skilled in the art that various changes in form and detail may be made therein without departing from the spirit and scope of the present disclosure. For example, various steps of the described methods may be executed in a different order or executed sequentially, combined, further divided, replaced with alternate steps, or removed entirely. In addition, various functions illustrated in the methods or described elsewhere in the disclosure may be combined to provide additional and/or alternate functions. Therefore, the claims should be interpreted in a broad manner, consistent with the present disclosure.

What is claimed is:

1. A method, comprising:
introducing an acid solution having ethanol and an acid to a substrate and cleaning the substrate using the acid solution;
applying an ultrasonic wave to the acid solution substantially during the cleaning of the substrate; and
performing a fine cleaning to the substrate after the cleaning of the substrate with the acid solution.

2. The method of claim 1, wherein the introducing of the acid solution includes introducing acetic acid.

3. The method of claim 1, further including introducing acetone into the acid solution.

4. The method of claim 3, further including blending the acid solution with about 0 to 8 acetone, 1 to 8 ethanol, and 0.1 to 5 acetic acid in relative volume, respectively.

5. The method of claim 3, further including maintaining the acid solution at a temperature ranging between about 10° C. and 50° C.

6. The method of claim 3, wherein the cleaning of the substrate has a duration ranging between about 10 minutes and 80 minutes.

7. The method of claim 1, wherein the applying of the ultrasonic wave includes applying the ultrasonic wave with a power ranging between about 10 and 200 Watts.

8. The method of claim 1, wherein the applying of the ultrasonic wave includes applying the ultrasonic wave with a frequency of about 360 KHz.

9. The method of claim 1, wherein the substrate is a mask.

10. The method of claim 9, wherein the mask includes a material selected from the group consisting of SiO₂, Cr, and MoSiONₓ.

11. The method of claim 1, wherein the performing of the fine cleaning includes:
performing a cleaning of the substrate using a SC-1 solution blended with about 0-1 NH₄OH, 2 H₂O₂, and 200-600 H₂O in relative volume, respectively; and
applying to the SC-1 solution a megasonic wave having a power ranging between about 100 and 550 Watts.

12. The method of claim 11, wherein the performing of the fine cleaning further includes performing a drying process using isopropyl alcohol (IPA) for a duration ranging between about 20 to 150 seconds.

13. The method of claim 12, wherein the performing of the drying process includes maintaining the IPA at a temperature ranging between about 50° C. and 150° C.

14. The method of claim 1, further including a physical cleaning using de-ionized water (DIW) and applying an ultrasonic wave to the DIW after the cleaning of the substrate using the acid solution.

15. The method of claim 14, wherein the physical cleaning includes introducing the DIW with at least one of showering, vaporization, dipping and combinations thereof.

16. The method of claim 14, wherein the physical cleaning includes introducing to the substrate an ultrasonic wave having a power ranging between about 10 and 200 Watts.

17. The method of claim 14, wherein the physical cleaning has a duration ranging between about 10 seconds and 120 seconds.

18. A system, comprising:
a de-glue module designed for removing a pellicle from substrate of a reticle through removing glue disposed at an interface between the pellicle and the substrate;
a chemical dispenser designed for providing various chemicals to form an acid solution used to clean the reticle;
an ultrasonic source designed for providing various ultrasonic waves used to enhance the cleaning of the substrate; and
a temperature control module configured to control a temperature of the various chemicals.

19. The system of claim 18, further comprising:
an exhaust module designed for removing exhaustive gases and used chemicals; and
a drying module designed for drying the substrate.

20. The system of claim 18, further comprising:
a mechanism configured to automatically transfer the substrate; and
an agitation module configured to provide agitation to various solutions.

21. A method, comprising:
performing a chemical cleaning of a substrate using an acid solution containing acetone, ethanol, and acetic acid;
performing a physical cleaning of the substrate using deionized water (DIW); and
performing a fine cleaning using a solution containing NH₄OH, H₂O₂, and H₂O.
